(19) United States
(12) Patent Application Publication
(10) Pub. No.: US 2015/0085555 A1
(43) Pub. Date: Mar. 26, 2015

(54) PACKAGED MEMORY DIES THAT SHARE A CHIP SELECT LINE

(71) Applicants: David G. Carpenter, Cypress, TX (US); Reza M. Bacchus, Spring, TX (US); William C. Hallowell, Spring, TX (US)

(72) Inventors: David G. Carpenter, Cypress, TX (US); Reza M. Bacchus, Spring, TX (US); William C. Hallowell, Spring, TX (US)

(21) Appl. No.: 14/394,260

(22) PCT Filed: May 1, 2012
(86) PCT No.: PCT/US2012/035914

§ 371 Date: Oct. 13, 2014

(51) Int. Cl. G11C 8/12; G11C 29/42; G11C 5/02

(52) U.S. Cl. CPC G11C 8/12; G11C 5/02; G11C 29/42
USPC 365/51

(57) ABSTRACT

An apparatus includes a memory module, and the memory module includes a package. The package contains memory dies, and the memory dies share a chip select line.

### BACKGROUND

Packaging refers to encasing a semiconductor die in a housing to prevent physical damage to the die and contacts leading into the die. The housing may be made of plastic or a ceramic material. Dual in-line memory modules (“DIMMs”) may comprise dynamic random access memory (“DRAM”) housed in various numbers of packages on both sides of a circuit board.

Two dies may reside in the same package. “Opposing face” dies reside in the same package and are adjacent in a direction normal to the plane of the board. The die closest to the board is “face down” (the contacts emanate from the side of the die toward the board) and the die furthest from the board is “face up” (the contacts emanate from the side of the die away from the board). “Dual face up” dies reside in the same package and are adjacent in a direction normal to the plane of the board as well. Both the die closest to the board and the die furthest from the board have contacts that emanate from the side of the die furthest from the board. “Dual face down” dies reside in the same package and are also adjacent in a direction normal to the plane of the board. Both the die closest to the board and the die furthest from the board have contacts that emanate from the side of the die closest to the board.

### BRIEF DESCRIPTION OF THE DRAWINGS

For a detailed description of various examples, reference will now be made to the accompanying drawings in which:

FIG. 1 illustrates a package of memory dies in accordance with at least some illustrated examples;

FIG. 2 illustrates a memory module comprising at least one package of memory dies in accordance with at least some illustrated examples; and

FIG. 3 illustrates a system of error correction comprising at least one package of memory dies in accordance with at least some illustrated examples.

### DETAILED DESCRIPTION

Inserting two 4-bit dies side-by-side, not adjacent or partially adjacent in a direction normal to the plane of the board, into the same 8-bit package allows for numerous benefits, especially when multiple such packages are used on a memory module. For example, if an entire die fails (each bit contains errors), error correction techniques can allow for continued operation of the remaining dies and memory module. Considering use of one 8-bit die instead of two 4-bit dies, if greater than four bits of the 8-bit die produce errors, at least one of the errors cannot be corrected. As such, the memory module should be replaced. Additionally, a memory module comprised of 8-bit dies cannot continue operation if an entire die fails. Also, because two 4-bit dies can be placed side-by-side in an 8-bit package, the dies can be identical as opposed to stacked dies that require the upper die to have longer contacts than the lower die due to the upper die's further distance from the board.

An 8-bit die comprises eight data lines, one data line for each bit, and may also be called a “by 8 die” or “x8 die.” A package designed to receive an 8-bit die may also be called a “by 8” or “x8” package. When a package receives an 8-bit die, the package may operate in an 8-bit memory mode. In the 8-bit memory mode, eight pins of the package, DQ0-DQ7, corresponding to the eight data lines of the 8-bit die may be used to send and receive data.

Two pins, TDQS and TDQS#, may be used to provide termination resistance in 8-bit memory mode. Termination resistance prevents signal distortion and timing problems, and may be provided by a resistor coupled to the pins. The TDQS pin may toggle between a termination resistance function and a data mask (“DM”) function in 8-bit memory mode. Input or write data may be masked by a pattern of bits using the DM function. When TDQS is enabled, the DM function is not supported. When TDQS is disabled, the DM function is provided.

Two pins, DQS and DQS#, may be used as differential data strobes in 8-bit memory mode. The data strobe pins are used to signal when the die should read and write to the data lines. For example, reads may occur at the edge of the DQS signal, and writes may occur during the center of the DOS signal. At other times, the DQS# signal is asserted.

One pin, ZQ, may be used as an external reference pin for output drive calibration, i.e., a reference voltage. This pin may be coupled to an external resistor, e.g., a 2400 resistor in at least one example, and the resistor may be coupled to a grounding pin. The ZQ pin may be adjacent to a pin which is not used in 8-bit memory mode.

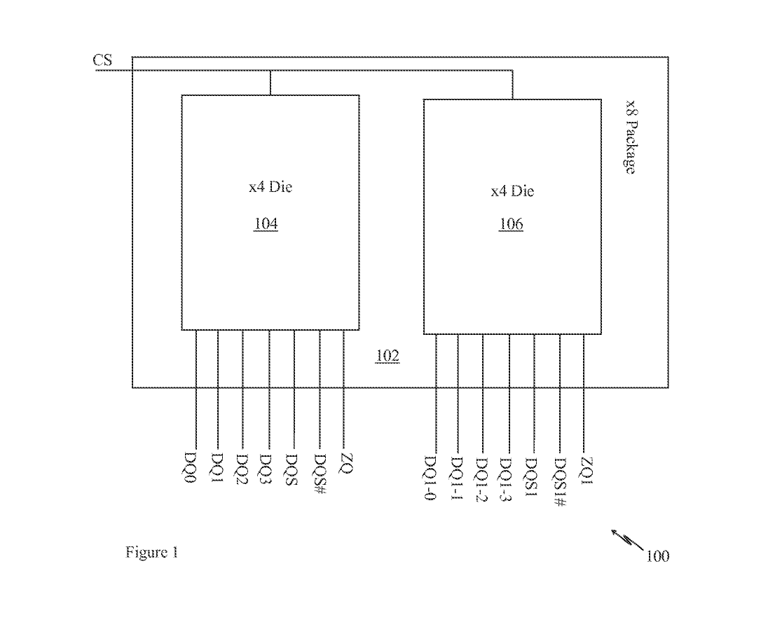

FIG. 1 illustrates a top view of a system 100 of packaged memory dies comprising a package 102 in accordance with at least some illustrated examples. The system 100 may comprise a package 102 that, in at least one example, is designed to receive an 8-bit die, but instead receives two 4-bit dies 104, 106. In at least one example, the two 4-bit dies reside in the same physical dimensions used to receive an 8-bit die. As such, the package 102 may be 7.85-9.15 millimeters wide and 10.85-11.15 millimeters long. The package 102 may be 0.96-1.2 millimeters thick including pins, or the package 102 may be 0.7-0.95 millimeters thick excluding pins. Other dimensions may be used in various other examples. When the package 102 receives an 8-bit die, the package may operate in an 8-bit memory mode. When the package 102 receives two 4-bit dies, the package 102 may operate in a 2×4-bit memory mode. The 2×4-bit memory mode is shown in FIG. 1.

The package 102 may receive two 4-bit dies 104, 106 in at least one example. A 4-bit die comprises four data lines, one data line for each bit, and may be called a “by 4 die” or “x4 die.” In at least one example, the two memory dies 104, 106 (or any portion of the two memory dies 104, 106) may not be adjacent in a direction normal to a plane defined by a board on which the dies 104, 106 reside. In other words, the dies 104, 106 may not be stacked one on top of the other or one partially on top of the other. Rather, the dies 104, 106 may be received side-by-side in the package 102. When the package 102 receives two 4-bit dies, the package 102 may operate in 2×4-bit memory mode.

Each die 104, 106 may comprise 4 data lines ending in pins outside the casing portion of the package 102 in at least one example. The data pins for the data lines of die 104 are labeled DQ0, DQ1, DQ2, and DQ3. The data pins for the data lines for die 106 are labeled DQ1-0, DQ1-1 DQ1-2, and DQ1-3. The memory dies 104, 106 do not share data lines in at least one example. That is, no data line on memory die 104 is coupled to a data line on memory die 106 in at least one example. For example, DQ0 is not connected to DQ1-0. Similarly, DQ1 is not connected to DQ1-1 DQ2 is not connected to DQ1-2, and DQ3 is not connected to DQ1-3. As such, the eight data lines spanning the two dies 104, 106 are independent of each other. The data pins used in 8-bit memory mode may act as data pins for two 4-bit dies in 2×4-bit memory mode. For example, four of the data pins used in 8-bit memory mode. DQ0-DQ3, may be used for the four data pins of the first die 104 in 2×4-bit memory mode, DQ0-DQ3. The remaining four data pins used in 8-bit memory mode, DQ4-DQ7, may be used for the four data pins of the second die 106 in 2×4-bit memory mode, DQ1-0-DQ1-3. That is, DQ4 may be used for DQ1-0, DQ5 may be used for DQ1-1, DQ6 may be used for DQ1-2, and DQ7 may be used for DQ1-3.

Each die 104, 106 may be coupled to a pair of differential data strobe pins in at least one example. Two of the pins used in 8-bit memory mode, DQS and DQS#, may be used as data strobe pins for die 104, DOS and DQS#. Two of the pins used in 8-bit memory mode, TDQS and TDQS#, may be used as data strobe pins for die 106, DQS1 and DQS1#. The strobe lines are used to signal when the dies should read and write to the data lines. Regarding the first die 104, reads may occur at the edge of the DQS signal, and writes may occur during the center of the DQS signal. At other times, the DQS# signal is asserted. Similarly, for the second die 106, reads may occur at the edge of the DQS1 signal, and writes may occur during the center of the DQS1 signal, At other times, the DQS1# signal is asserted.

Each die 104, 106 may be coupled to a pin used as an external reference pin for output drive calibration, i.e., a reference voltage, in at least one example. One of the pins used in 8-bit memory mode, ZQ, may be used as the external reference pin for the first die 104, ZQ. An unused pin adjacent to ZQ in 8-bit memory mode may be used as the external reference pin for the second die 106, ZQ1, in 2×4-bit memory mode. As such, ZQ1 is adjacent to ZQ in 2×4-bit memory mode. These pins may each be coupled to an external resistor, e.g., a 240Ω resistor in at least one example, and the resistor may be coupled to a grounding pin.

In at least one example, the dies 104, 106 may share a chip select line, CS. As such, the dies 104, 106 may be selected together when the chip select line is asserted. By selecting the dies 104, 106 together, the eight data lines spanning the two dies 104, 106 may be used to read and write eight bits together across the multiple dies 104, 106. As such, in at least one example, die 104 stores one nibble of a byte that is read and written together with a second nibble of the byte stored by die 106. Accordingly, no adaptations are necessary to a memory module bus or routing signaling of the memory module when using a package 102 in 2×4 memory mode vis-à-vis 8-bit memory mode.

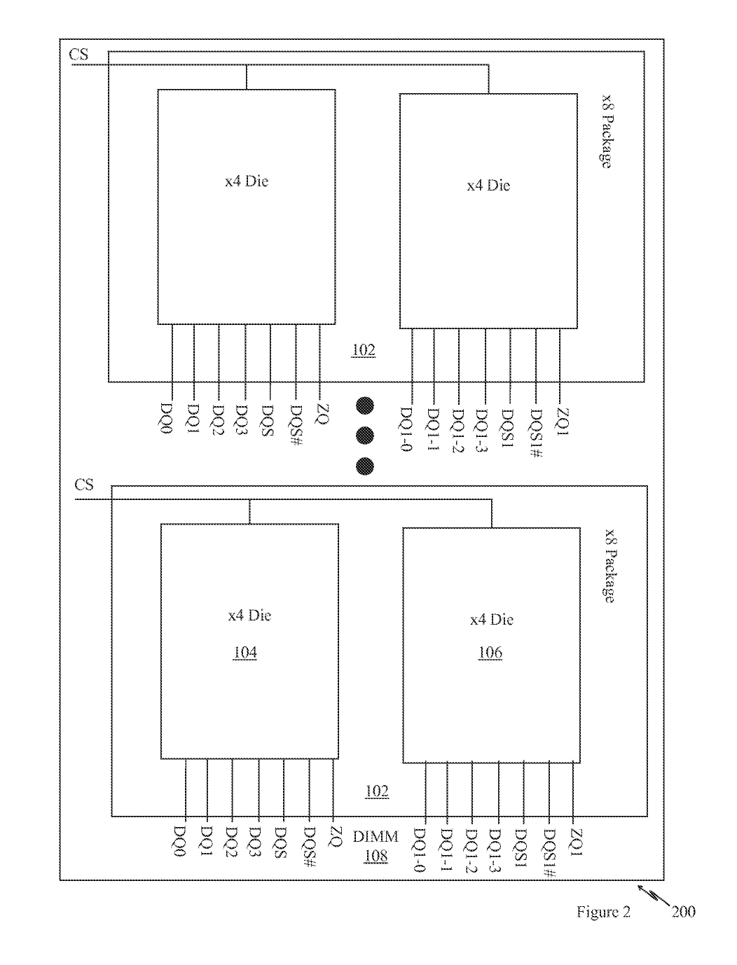

FIG. 2 illustrates an apparatus 200 comprising a memory module with at least one package 102 of memory dies 104, 106 in accordance with at least some illustrated examples. In at least one example, the memory module may comprise a dual in-line memory module (“DIMM”) 108, and the DIMM 108 may comprise multiple 8-bit packages 102, each comprising two 4-bit dies 104, 106. The dies 104, 106 may comprise dynamic random access memory (“DRAM”) in at least one example. In various examples, the DIMM 108 is one of several configurations, depending on the amount of DRAM used as well as the number of memory blocks, called ranks, the DIMM supports. A rank is an area or block of 64-bits created with some or all of the DRAM on the DIMM 108. In at least one example, the DIMM 108 may be a single-rank DIMM. A single-rank DIMM uses all of its DRAM to create a single block of 64 bits. In another example, the DIMM 108 may be a dual-rank DIMM. Dual-rank DIMMs improve memory capacity by placing two single-rank DIMMs on one module. A dual-rank DIMM produces two 64-bit blocks from two sets of DRAM on the DIMM. In another example, the DIMM 108 may be a quad-rank DIMM. Quad-rank DIMMs produce four 64-bit blocks from four sets of DRAM on the DIMM.

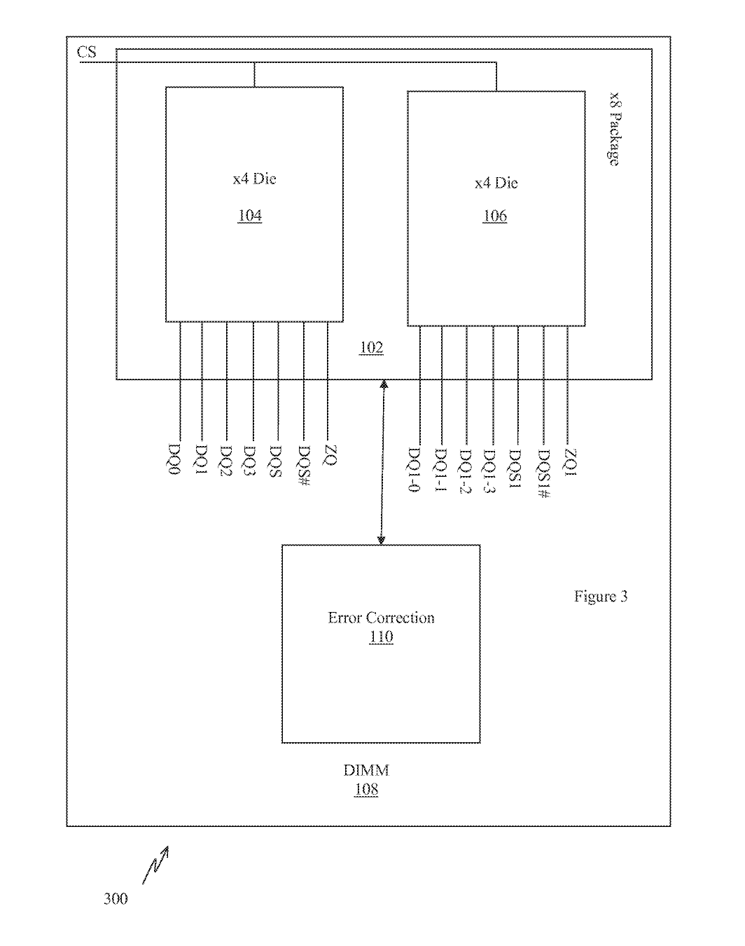

FIG. 3 illustrates a system 300 of error correction with at least one package 102 of memory dies 104, 106 in accordance with at least some illustrated examples. Memory modules are inherently susceptible to memory errors. Each set of DRAM stores data in an array, columns and rows, of capacitors. The DIMM 108 continuously refreshes power to the capacitors to preserve the data, and an operating voltage determines the level of the electrical charge in the capacitors.

Several events or conditions may cause errors in the capacitors. Memory errors are commonly classified according to the number of bits affected. An error in one bit of data is a single-bit error. An error in more than one bit of data is a multi-bit error. Memory errors are also classified as “hard” or “soft” errors. DRAM defects, bad solder joints, and data pin issues cause “hard” errors because the DIMM 108 consistently returns incorrect results. For example, a “stuck” memory cell returns the same bit value, even when a different bit is written to it. In contrast, soft errors are transient and non-repeating. They can be caused by an electrical disturbance inside the capacitor array, and can occur randomly. If an external event affects the charge of a capacitor, the data in the capacitor may become incorrect. Such an error may cause applications and operating systems using the DIMM 108 to crash, sometimes resulting in permanent data loss.

The system 300 may comprise a DIMM 108 comprising error correction logic 110 coupled to the x8 package 102. The error correction logic 110 may store 4 bits or 8 bits of error correction code (“ECC”), and the DIMM 108 comprising ECC may be called an ECC DIMM 108. Error correction logic 110 may encode information in a block of 8 bits to recover a single-bit error. The DIMM 108 may write data to a memory die 104, 106, and the error correction logic 110 may generate values called check bits by performing a repeatable mathematical function on the write data. The error correction logic 110 may add the check bits together to calculate a checksum, which is stored with the write data. Upon reading the data from the die 104, 106, the error correction logic may recalculate the checksum from the read data and compare it with the previously calculated and stored checksum determined from the write data. If the checksums are equal, then the data is valid and operation continues. If they differ, the data has an error. In the case of a single-bit error, or a multi-bit error affecting 4 or fewer bits, the error correction logic 110 may correct the error and output the corrected data so that the dies 104, 106 and DIMM 108 continue to operate.

In at least one example, the error correction logic 110 may correct multi-bit errors of the two memory dies 104, 106, the error correction logic 110 to continue correcting errors of the two memory dies 104, 106 when one of the dies fails (all 4-bits produce errors). The error correction logic 110 may detect and correct up to 4 bits in a 72 hit wide bus (64 bits plus 8 ECC bits), in at least one example. As such, if an entire 4-bit die 104, 106 fails, detection and correction is possible without replacement of the error producing die or DIMM 108. However, if the DIMM comprises an 8-bit die that fails, the error correction logic 110 may detect all the errors, but may only correct 4 of the faulty bits. As such, the 8-bit die should be replaced. Consequently, in at least one example, the DIMM 108 only comprises 4-bit dies in 8-bit packages 102.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An apparatus, comprising:
a memory module, comprising:
a package; and
memory dies contained in the package;
wherein the memory dies share a chip select line.

2. The apparatus of claim 1, wherein the memory dies do not share data lines.

3. The apparatus of claim 1, wherein the memory dies are not adjacent in a direction normal to a plane defined by a board of the memory module.

4. The apparatus of claim 1, wherein the package contains two 4-bit memory dies and the package is designed to receive one 8-bit memory die.

5. The apparatus of claim 4, wherein the package comprises two pins coupled to external resistors, one of the pins unused in an 8-bit memory mode.

6. The apparatus of claim 5, wherein the two pins are adjacent to each other.

7. The apparatus of claim 4, wherein the package comprises four data strobe pins, one of the data strobe pins used to provide termination resistance in an 8-bit memory mode.

8. The apparatus of claim 7, wherein another of he data strobe pins is used as a mask in an 8-bit memory mode.

9. A system, comprising:
a package;
a first memory die contained in the package; and
a second memory die contained in the package;
wherein the first memory die and second memory die do not share data lines.

10. The system of claim 9, wherein the first memory die and second memory die share a chip select line.

11. The system of claim 9, wherein the two memory dies are not adjacent in a direction normal to a plane defined by a board on which the dies reside.

12. The system of claim 9, wherein the package contains two 4-bit memory dies and the package is designed to receive one 8-bit memory die.

13. The system of claim 12, wherein the package comprises two pins coupled to external resistors, one of the pins unused in an 8-bit memory mode.

14. A system, comprising:
a dual in-line memory module (“DIM”), comprising:
a package designed to receive one 8-bit memory die; and
two 4-bit memory dies contained in the package, the two memory dies sharing a chip select line.

15. The system of claim 1, the DIM comprising error correction logic, the error correction logic to correct multi-bit errors of the two memory dies, the processor to continue correcting errors of the two memory dies when one of the dies fails.
